(19) United States
(12) Patent Application Publication
(10) Pub. No.: US 2020/0076421 A1
(43) Pub. Date: Mar. 5, 2020

(54) POWER-ON RESET SIGNAL GENERATOR AND ASSOCIATED ELECTRONIC DEVICE

(71) Applicant: Artery Technology Co., Ltd., Chongqing (CN)

(72) Inventors: Weitie Wang, Chongqing (CN); Baotian Hao, Chongqing (CN); Chao Li, Chongqing (CN)

(21) Appl. No.: 16/401,093

(22) Filed: May 1, 2019

(30) Foreign Application Priority Data
Sep. 3, 2018 (CN) 201811018369.X

(51) Int. Cl. H03K 17/22

(52) U.S. Cl. CPC H03K 17/22; H03K 2017/226

(57) ABSTRACT

A power-on reset signal generator and an associated electronic device are provided. The power-on reset signal generator includes a detection circuit and a comparator. The detection circuit detects the power-supply voltage to generate detection signals, and includes a plurality of sets of transistors, a first resistor and a second resistor, and at least one third resistor. Each set of transistors within the plurality of sets of transistors includes a first transistor and a second transistor respectively positioned on a first current path and a second current path within the detecting circuit. The first resistor and the second resistor are respectively positioned on the first current path and the second current path. The first current path and the second current path pass through the third resistor. The comparator receives the set of detection signals from the detection circuit, and compares the set of detection signals to generate a power-on reset signal.

### BACKGROUND OF THE INVENTION

### 1. Field of the Invention

The present invention relates to power-on control, and more particularly, to a power-on reset (POR) signal generator and an associated electronic device.

### 2. Description of the Prior Art

When powering up an electronic system, a certain period of time is required for the power supply to stabilize the voltage to its steady state value. During this transitional period, if no reset command is provided, the initial states of storage elements in general cannot be defined, and therefore the circuit behavior of the entire electronic system cannot be determined. According to the related art, a command signal for circuit initialization, such as a power-on reset signal, is typically required during or after the power-up period. The power-on reset signal should hold each of multiple circuits in the reset state until the power reaches the steady state voltage level, such as a voltage level that allows all the circuits to operate normally.

However, some problems may occur in the above design. For example, the voltage level of a certain voltage detection point (e.g. a voltage threshold) for generating the power-on reset signal is typically influenced by the temperature and the manufacturing process, and this problem is even worse in advanced manufacturing processes. Hence, there is a need for a novel mechanism to improve the overall performance without introducing a side effect or in a way that is less likely to introduce a side effect.

### SUMMARY OF THE INVENTION

An objective of the present invention is to provide a power-on reset signal generator and an associated electronic device, in order to solve the above-mentioned problem.

Another objective of the present invention is to provide a power-on reset signal generator and an associated electronic device, in order to achieve an optimal performance of the electronic device without introducing a side effect or in a way that is less likely to introduce a side effect.

At least one embodiment of the present invention provides a power-on reset signal generator which may comprise a detection circuit and a comparator. The detection circuit is coupled between a power-supply voltage and a ground voltage, and the detection circuit is arranged to perform detection operations on the power-supply voltage to generate a set of detection signals, wherein the detection circuit comprises a plurality of sets of transistors, a first resistor and a second resistor, and at least one third resistor. The plurality of sets of transistors are stacked and coupled between the power-supply voltage and the ground voltage, wherein each set of transistors within the plurality of sets of transistors comprises a first transistor and a second transistor respectively positioned on a first current path and a second current path within the detecting circuit. The first resistor and the second resistor are coupled between two sets of transistors within the plurality of sets of transistors, wherein the first resistor and the second resistor are respectively positioned on the first current path and the second current path. The at least one third resistor is coupled between the power-supply voltage and the plurality of sets of transistors, wherein the first current path and the second current path pass through the at least one third resistor. In addition, the comparator is coupled to the first resistor and the second resistor, and is arranged to receive the set of detection signals from the detection circuit, and compare the set of detection signals to generate a power-on reset signal.

At least one embodiment of the present invention provides an electronic device equipped with the above-mentioned power-on reset signal generator. The electronic device may comprise a processing circuit, a power-supply circuit and a reset control circuit, wherein the power-supply circuit is coupled to the processing circuit, and the reset control circuit is coupled to the processing circuit and the power-supply circuit. The processing circuit may be arranged to control operations of the electronic device, and the power-supply circuit may be arranged to provide power to the processing circuit. In addition, the reset control circuit may be arranged to perform reset control on the processing circuit according to the power-on reset signal, wherein the reset control circuit comprises the power-on reset signal generator.

An advantage provided by the present invention is that the power-on reset signal generator is capable of performing high accuracy control, and more particularly, the voltage detection point VPOR (e.g. a voltage threshold such as a reference voltage) required for generating the power-on reset signal will be independent of temperature and process, and the accuracy of the voltage detection point VPOR may correspond to the accuracy of the band-gap reference voltage. Hence, the power-on reset signal generator and the electronic device provided by the present invention can perform proper control to reach the optimal performance of the electronic device. Further, the power-on reset signal generator of the present invention can be configured to utilize any predetermined voltage level of various predetermined voltage levels as the voltage detection point VPOR, for being applied to various electronic systems.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a power-on reset signal generator according to an embodiment of the present invention.

FIG. 2 illustrates examples of detection signals of the architecture shown in FIG. 1 that vary with respect to the power-supply voltage.

FIG. 3 illustrates examples of power-on reset signals of the architecture shown in FIG. 1.

FIG. 4 is a diagram of an electronic device according to an embodiment of the present invention.

FIG. 5 is a diagram of a power-on reset signal generator according to another embodiment of the present invention.

### DETAILED DESCRIPTION

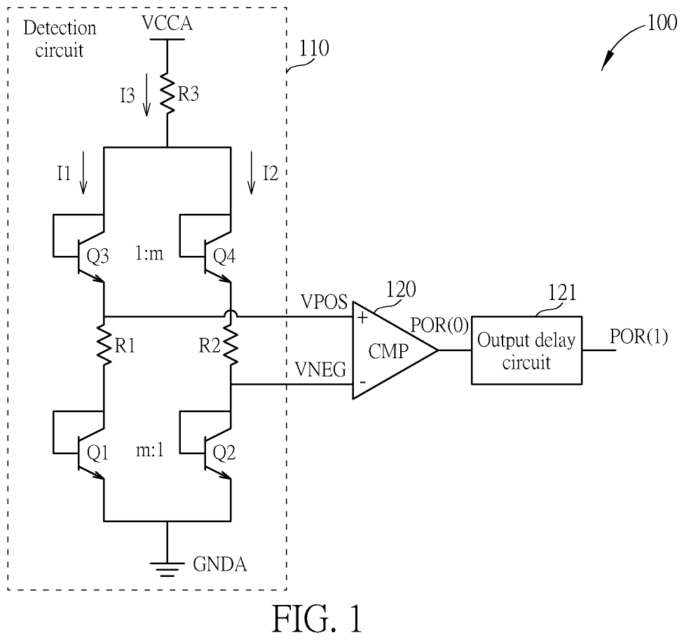

FIG. 1 is a diagram of a power-on reset signal generator 100 according to an embodiment of the present invention. The power-on reset signal generator 100 may comprise a detection circuit 110, a comparator 120 (labeled “CMP”) and an output delay circuit 121, wherein the detection circuit 110 is coupled between a power-supply voltage VCCA and a ground voltage GNDA, the comparator 120 is coupled to the detection circuit 110, and the output delay circuit 121 is coupled to the comparator 120, but the present invention is not limited thereto. In some embodiments, the output delay circuit 121 may be positioned outside the power-on reset signal generator 100 as a next-stage circuit.

According to this embodiment, the detection circuit 110 may comprise a plurality of sets of transistors that are stacked and coupled between the power-supply voltage VCCA and the ground voltage GNDA, such as N set of transistors (e.g. N is an integer greater than one), and each set of transistors {Q (2n−1), Q (2n)} within the plurality of sets of transistors (such as the N set of transistors) may comprise a first transistor Q(2n−1) and a second transistor Q(2n) respectively positioned on a first current path and a second current path within the detection circuit 110 (such as the respective current paths of the currents I1 and I2), wherein n may represent an integer within the interval [1, N]. Although this embodiment adopts “N=2” as an example, the present invention is not limited thereto. As shown in FIG. 1, the first set of transistors (such as {Q(2n−1), Q(2n)}, wherein n=1) may comprise transistors Q1 and Q2, and the second set of transistors (such as {Q(2n−1), Q(2n)}, wherein n=2) may comprise transistors Q3 and Q4. Further, the detection circuit 110 may comprise resistors R1 and R2 that are respectively positioned on the first current path and the second current path and are coupled between two sets of transistors within the plurality of sets of transistors. More particularly, the two sets of transistors may comprise the first set of transistors Q1 and Q2, and the second set of transistors Q3 and Q4. In addition, the detection circuit 110 may comprise at least one resistor (e.g. one or more resistors) coupled between the power-supply voltage VCCA and the plurality of sets of transistors, such as the resistor R3, wherein the current I3 is equal to the summation of the currents I1 and I2, and the first current path and the second current path pass through the aforementioned at least one resistor such as the resistor R3, but the present invention is not limited thereto. In some embodiments, the aforementioned at least one resistor may comprise two resistors respectively positioned on the first current path and the second current path, and these two resistors may have the same resistance value. Note that implementing the aforementioned at least one resistor with a single resistor (such as the resistor R3) may reduce the circuit area.

As shown in FIG. 1, the first current path (such as the current path of the current I1) passes through the resistor R1 and the first transistor Q(2n−1) within each set of transistors {Q(2n−1), Q(2n)} (e.g. the transistor Q1 or Q3), and the second current path (such as the current path of the current I2) passes through the resistor R2 and the second transistor Q(2n) within each set of transistors {Q(2n−1), Q(2n)} (e.g. the transistor Q2 or Q4). Each transistor within each set of transistors {Q(2n−1), Q(2n)} is configured as a two-terminal component, and two terminals within multiple terminals of the aforementioned each transistor are coupled to each other. More particularly, the two-terminal component may represent a diode-connected transistor. For example, the aforementioned each transistor may be an NPN transistor, and the multiple terminals may comprise an emitter terminal, a base terminal and a collector terminal, wherein the base terminal and the collector terminal are coupled to each other. As a result, the detection circuit 110 may utilize the voltage difference VBE between the base and the emitter as the basis of a reference voltage, and may utilize each set of transistors {Q (2n−1), Q (2n)} as a band-gap core. With the stacked or cascoded N band-gap cores (e.g. N=2 in this embodiment), the detection circuit 110 may obtain the reference voltage such as the voltage detection point VPOR, wherein VPOR=N·VBG, and VBG represents a bandgap voltage parameter (which will be explained later). In this embodiment, the first ratio RATIO(1) between the respective specific parameters of the first transistor and the second transistor within the first set of transistors (e.g. the transistors Q1 and Q2) is equal to the reciprocal of the second ratio RATIO(2) between the respective specific parameters of the first transistor and the second transistor within the second set of transistors (e.g. the transistors Q3 and Q4). The first ratio RATIO (1) may represent the ratio of the specific parameter of the first transistor (e.g. the transistor Q1) within the first set of transistors to the specific parameter of the second transistor (e.g. the transistor Q2) within the first set of transistors, such as m:1 that is equal to (m/1), and the second ratio RATIO(2) may represent the ratio of the specific parameter of the first transistor (e.g. the transistor Q3) within the second set of transistors to the specific parameter of the second transistor (e.g. the transistor Q4) within the second set of transistors, such as 1:m that is equal to (1/m), wherein m is not equal to 1 and is greater than 1, RATIO (1)=(m/1)=m, and RATIO(2)=(1/m)=1/m. For example, the specific parameter may represent emitter current I_{E}, but the present invention is not limited thereto.

In addition, the comparator 120 is coupled to the resistors R1 and R2. For example, the comparator 120 comprises a positive input terminal and a negative input terminal (respectively labeled “+” and “−”). A first terminal and a second terminal of the resistor R1 (such as the upper terminal and the lower terminal thereof) are coupled to the power-supply voltage VCCA and ground voltage GNDA via multiple partial paths of the first current path (such as the upper path and the lower path of the resistor R1), respectively, and a first terminal and a second terminal of the resistor R2 (such as the upper terminal and the lower terminal thereof) are coupled to the power-supply voltage VCCA and ground voltage GNDA via multiple partial paths of the second current path (such as the upper path and lower path of the resistor R2), respectively. The positive input terminal of the comparator 120 is coupled to the first terminal (such as the upper terminal) of the resistor R1, and the negative input terminal of the comparator 120 is coupled to the second terminal (such as the lower terminal) of the resistor R2.

Based on the architecture shown in FIG. 1, the detection circuit 110 may perform detection operations on the power-supply voltage VCCA to generate a set of detection signals VPOS and VNEG. The comparator 120 may receive the set of detection signals VPOS and VNEG from the detection circuit 110, and compare the set of detection signals VPOS and VNEG to generate a power-on reset signal POR(0). The output delay circuit 121 may delay the power-on reset signal POR(0) to generate a delayed version of the power-on reset signal POR(0), for being utilized as another power-on reset signal, such as the power-on reset signal POR(1). For example, the output delay circuit 121 may control the delay amount of the power-on reset signal POR(1) with respect to the power-on reset signal POR(0) to be equal to a predetermined value TD. As a result, an electronic device equipped with the power-on reset signal generator 100 may perform reset control according to the power-on reset signal POR(0) (more particularly, the delayed version thereof, such as the power-on reset signal POR(1)).

For better understanding, the parameters of some components (e.g. R1) may be expressed with the same symbol in Italics (e.g. R1) in the following descriptions. According to some embodiments, some implementation details of the architecture shown in FIG. 1 may be described as follows. In the beginning of powering up the electronic device, the power-supply voltage VCCA may rise from 0 Volt (V) and be applied to the detection circuit 110. When the voltage level of the detection signal VPOS is equal to the voltage level of the detection signal VNEG, this indicates that the power-supply voltage VCCA has reached the voltage detection point VPOR. In order to obtain a high accuracy voltage detection point VPOR, it is required that the respective resistance values R1 and R2 of the resistors R1 and R2 are equal to each other (i.e. R1=R2), and an appropriate resistance value R3 of the resistor R3 is also required in order to obtain the result of: VPOR=2·≈2.42 (V). In the following, equations may be derived with the presumption of “VPOS=VNEG” and it is assumed that m=8. It is known that the first current path comprises the resistor R1 and the transistors Q1 and Q3, and the second current path comprises the resistor R2 and the transistors Q2 and Q4. To make the currents I1 and I2 flow through the same path, components in the detection circuit 110 are configured to control the resistors R1 and R2 to be equal to each other (e.g. R1=R2), control the transistors Q1 and Q4 (e.g. characteristic parameters thereof) to be equal to each other, and control the transistors Q2 and Q3 (e.g. characteristic parameters thereof) to be equal to each other. Since the currents I1 and I2 flow through the same path, the magnitude of the currents I1 and I2 will be equal to each other (i.e. I1=I2). The related equations may be expressed as follows:

$$I 1 = I 2 = ( Δ {V}_{BE} / R 1 ) ;$$

$$Δ {V}_{BE} = {V}_{BE 2} - {V}_{BE 1} = {V}_{T} \cdot ln ( m ) = {V}_{T} \cdot ln ( 8 ) ;$$

$$\begin{matrix}VPOR = {V}_{BE 1} + {V}_{BE 3} + I 1 \cdot R 1 + ( I 1 + I 2 ) \cdot R 3 \\ = 2 \cdot {V}_{BE} + ( Δ {V}_{BE} / R 1 ) \cdot ( R 1 + 2 \cdot R 3 )\end{matrix} ; and$$

$$VPOR = 2 \cdot ( {V}_{BE} + ( ( R 1 + 2 \cdot R 3 ) / ( 2 \cdot R 1 ) ) \cdot Δ {V}_{BE} ) ;$$

wherein V_{BE1}, V_{BE2} and V_{BE3} represent the base-emitter voltages of the transistors Q1, Q2 and Q3, respectively, V_{T} represents the thermal voltage, and V_{BE} represents the average value of V_{BE1} and V_{BE3}. As a result, R1 and R3 can be selected to get:

(V_{BE}+((R1+2·R3)/(2·R1))·ΔV_{BE})=VBG,

to make

VPOR=2·VBG;

wherein the bandgap voltage parameter VBG may be equal to a predetermined value, for example, 1.2 (V), 1.21 (V), 1.22 (V), or another value close to these values (such as a certain value within the interval [1.1, 1.3]), but the present invention is not limited thereto.

Note that when related parameters (e.g. R1, R3, V_{BE}, ΔV_{BE}, etc.) of the detection circuit 110 have been decided, the bandgap voltage parameter VBG is equal to the predetermined value, and is not influenced by the temperature and the process. Hence, the voltage detection point VPOR is indeed independent of the temperature and the process, and the accuracy thereof may correspond to that of the bandgap reference voltage.

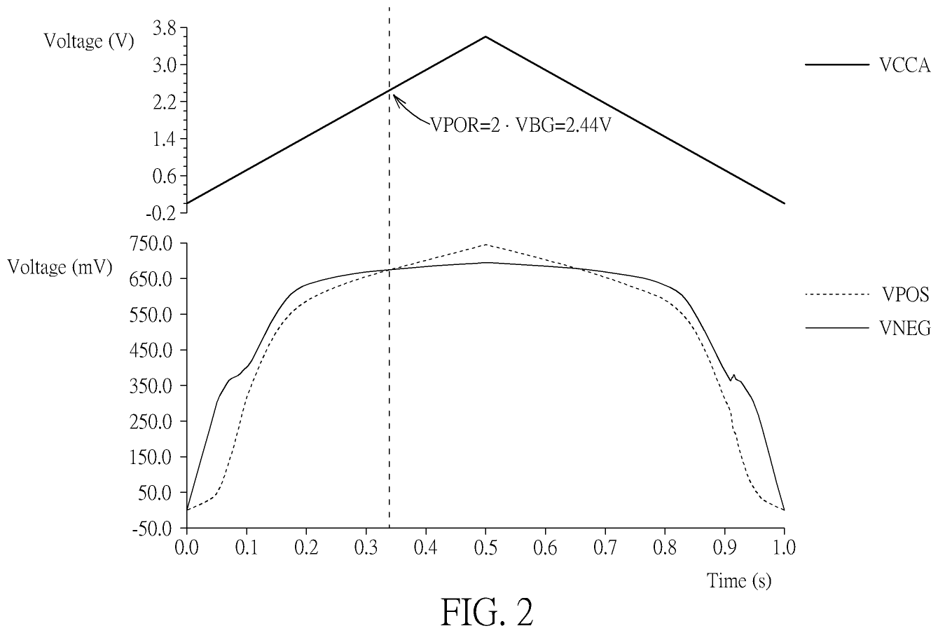

FIG. 2 illustrates examples of detection signals VPOS and VNEG of the architecture shown in FIG. 1 that vary with respect to the power-supply voltage VCCA, but the present invention is not limited thereto. The relationship between the detection signals VPOS and VNEG may indicate whether the power-supply voltage VCCA has reached the voltage detection point VPOR or not. For example, when the voltage levels of the detection signals VPOS and VNEG are equal to each other, this means that the power-supply voltage VCCA has reached the voltage detection point VPOR. In this embodiment, VBG=1.22 (V), and VPOR=2·VBG=2.44 (V).

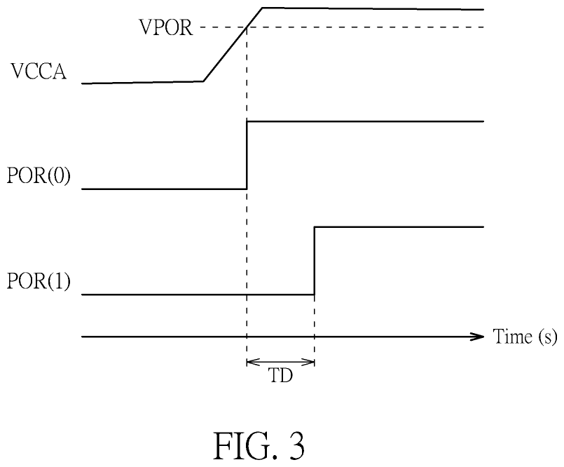

FIG. 3 illustrates examples of power-on reset signals POR(0) and POR(1) of the architecture shown in FIG. 1, but the present invention is not limited thereto. The power-on reset signal POR(0) may be regarded as a non-delayed power-on reset signal, and the power-on reset signal POR(1) may be regarded as a delayed power-on reset signal. Based on the architecture shown in FIG. 1, the rising edge of the power-on reset signal POR(0) corresponds to the time when the power-supply voltage VCCA reaches the voltage detection point VPOR.

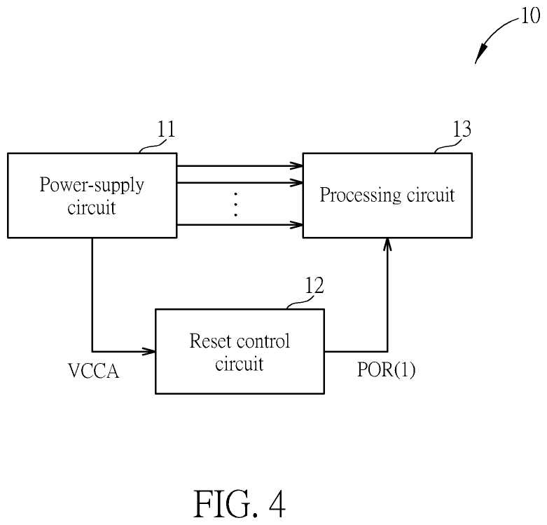

FIG. 4 is a diagram of an electronic device 10 according to an embodiment of the present invention, wherein the electronic device 10 may be an example of the aforementioned electronic device. The electronic device 10 may comprise a power-supply circuit 11, a reset control circuit 12 and a processing circuit 13, wherein these circuits are coupled to one another. For example, the reset control circuit 12 may comprise the power-on reset signal generator 100, and the processing circuit 13 may comprise a processor, microprocessor, and/or microcontroller, and more particularly, may comprise associated circuits such as storage elements, for example, memories, digital registers and analog integrators, but the present invention is not limited thereto. The processing circuit 13 may control operations of the electronic device 10, and the power-supply circuit may provide power to the processing circuit 13, and more particularly, may output at least one power-supply voltage (e.g. one or more power-supply voltages) that comprises the power-supply voltage VCCA. Further, the reset control circuit 12 may perform reset control on the processing circuit 13 according to the power-on reset signal POR(0) (more particularly the delayed version thereof, such as the power-on reset signal POR(1)).

According to some embodiment, the reset control circuit 12 may monitor whether the power-supply voltage VCCA is higher than the minimum operating voltage of the processing circuit 13. For example, the voltage detection point VPOR may be equal to (or approximately equal to) the minimum operating voltage. After the electronic device 10 is powered up, the reset control circuit 12 may control the processing circuit 13 to enter the reset state to complete the initialization of the associated circuits such as the storage elements (e.g. the digital registers and the analog integrators), in order to determine the initial states of the storage elements.

According to some embodiments, after the electronic device 10 is powered up, the reset control circuit 12 may utilize the power-on reset signals POR(0) and/or POR(1) to keep the processing circuit 13 in the reset state, until the power-supply voltage VCCA has exceeded the power-on reset threshold value (such as the voltage detection point VPOR) for a specific duration of delay.

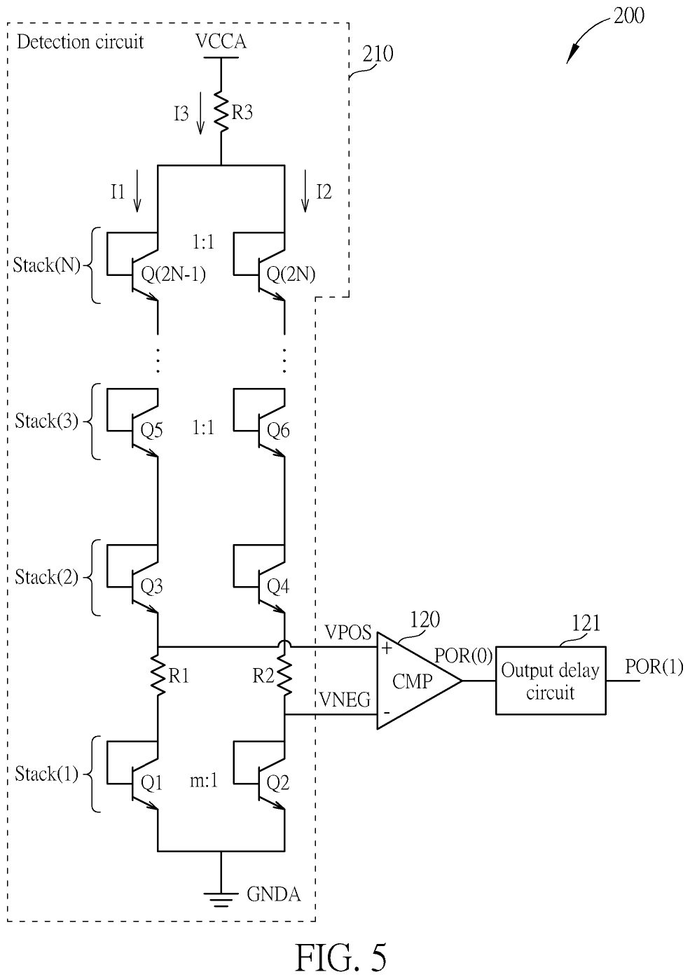

FIG. 5 is a diagram of a power-on reset signal generator 200 according to another embodiment of the present invention. In comparison with the architecture shown in FIG. 1, the detection circuit 110 is replaced with the detection circuit 210 in this embodiment. In a situation where N>2, the first set of transistors (such as {Q (2n−1), Q (2n)}, wherein n=1) may comprise the transistors Q1 and Q2, and may be referred to as the stack Stack(1); the second set of transistors (such as {Q(2n−1), Q(2n)}, wherein n=2) may comprise the transistors Q3 and Q4, and may be referred to as the stack Stack(2); the third set of transistors (such as {Q(2n−1), Q(2n)}, wherein n=3) may comprise the transistors Q5 and Q6, and may be referred to as the stack Stack(3), and so on. Similarly, the N-th set of transistors (such as {Q(2n−1), Q(2n)}, wherein n=N) may comprise the transistors Q(2N−1) and Q(2N), and may be referred to as the stack Stack(N). Further, the third ratio RATIO(3) between the respective specific parameters of the first transistor and the second transistor within the third set of transistors (e.g. the transistors Q5 and Q6) is equal to 1, wherein the third ratio RATIO 3) may represent the ratio of the specific parameter of the first transistor (e.g. the transistor Q5) within the third set of transistors to the specific parameter of the second transistor (e.g. the transistor Q6) within the third set of transistors, such as 1:1 that is equal to (1/1), and so on. Similarly, the N-th ratio RATIO (N) between the respective specific parameters of the first transistor and the second transistor within the N-th set of transistors (e.g. the transistors Q(2N−1) and Q(2N)) is equal to 1, wherein the N-th ratio RATIO(N) may represent the specific parameter of the first transistor (e.g. the transistor Q(2N−1)) within the N-th set of transistors to the specific parameter of the second transistor (e.g. the transistor Q(2N)) within the N-th set of transistors, such as 1:1 that is equal to (1/1).

In any of the embodiments respectively shown in FIGS. 1 and 5, the equation of “VPOR=N·VBG” is always valid. For example, the power-on reset signal generator 100 may utilize the voltage detection point VPOR of the voltage detection that the detection circuit 110 performs on the power-supply voltage VCCA as a threshold value for controlling whether to change the logical state of the power-on reset signal POR(0), wherein VPOR=N·VBG, and N=2. In another example, the power-on reset signal generator 200 may utilize the voltage detection point VPOR of the voltage detection that the detection circuit 210 performs on the power-supply voltage VCCA as the threshold value to control whether to change the logical state of the power-on reset signal POR(0), wherein VPOR=N·VBG, and N>2. Further, through configuring the resistor R1 and the aforementioned at least one resistor such as R3, the voltage detection point VPOR is equal to N times the bandgap voltage parameter VBG (i.e. VPOR=N·VBG). Configuring the resistor R1 and the aforementioned at least one resistor such as R3 may comprise controlling the resistance values of these resistors (e.g. the resistance values R1 and R3) to conform to a predetermined condition (e.g., (V_{BE}+((R1+2·R3)/(2·R1))·ΔV_{BE})=VBG).

The present invention provides a high accuracy power-on reset signal generator (such as the power-on reset signal generators 100 and 200), wherein the voltage detection point VPOR thereof is independent of the temperature and the process, and the accuracy of the voltage detection point VPOR may correspond to the accuracy of the bandgap reference voltage. More particularly, the high accuracy power-on reset signal generator may be applied to the power management of various circuits (e.g. a system-on-chip (SOC), a micro control unit (MCU), an intellectual property (IP) module, etc.). For example, in a situation where the bandgap voltage parameter VBG is equal to 1.2 V, by respectively configuring the detection circuit with N=2, N=3, N=4, and so on, the high accuracy power-on reset signal generator can provide the power-on reset signal POR(such as the power-on reset signals POR(1) and POR(2)) corresponding to the voltage detection point VPOR (e.g. 2.4 V, 3.6 V, 4.8 V, etc.) In comparison with the related art, the application range of the present invention is much wider, and the voltage detection point VPOR is not influenced by the temperature and the process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A power-on reset signal generator, comprising:
a detection circuit, coupled between a power-supply voltage and a ground voltage, the detection circuit arranged to perform detection operations on the power-supply voltage to generate a set of detection signals, wherein the detection circuit comprises:
a plurality of sets of transistors, stacked and coupled between the power-supply voltage and the ground voltage, wherein each set of transistors within the plurality of sets of transistors comprises:
a first transistor and a second transistor respectively positioned on a first current path and a second current path within the detecting circuit;
a first resistor and a second resistor, coupled between two sets of transistors within the plurality of sets of transistors, wherein the first resistor and the second resistor are positioned on the first current path and the second current path, respectively; and
at least one third resistor, coupled between the power-supply voltage and the plurality of sets of transistors, wherein the first current path and the second current path pass through said at least one third resistor; and
a comparator, coupled to the first resistor and the second resistor, the comparator arranged to receive the set of detection signals from the detection circuit, and compare the set of detection signals to generate a power-on reset signal.

2. The power-on reset signal generator of claim 1, wherein the first current path passes through the first resistor and the first transistor within said each set of transistors, and the second current path passes through the second resistor and the second transistor within said each set of transistors.

3. The power-on reset signal generator of claim 1, wherein each transistor within said each set of transistors is configured as a two-terminal component, and two terminals within multiple terminals of said each transistor are coupled to each other.

4. The power-on reset signal generator of claim 3, wherein the two-terminal component represents a diode-connected transistor.

5. The power-on reset signal generator of claim 3, wherein the multiple terminals of said each transistor comprise an emitter terminal, a base terminal and a collector terminal, and the base terminal and the collector terminal are coupled to each other.

6. The power-on reset signal generator of claim 1, wherein the two sets of transistors comprise a first set of transistors and a second set of transistors, and a first ratio between respective specific parameters of the first transistor within the first set of transistors and the second transistor within the first set of transistors is equal to the reciprocal of a second ratio between the respective specific parameters of the first transistor within the second set of transistors and the second transistor within the second set of transistors.

7. The power-on reset signal generator of claim 6, wherein the first ratio represents the ratio of the specific parameter of the first transistor within the first set of transistors to the specific parameter of the second transistor within the first set of transistors, and the second ratio represents the ratio of the specific parameter of the first transistor within the second set of transistors to the specific parameter of the second transistor within the second set of transistors.

8. The power-on reset signal generator of claim 1, further comprising:
an output delay circuit, coupled to the comparator, the output delay circuit arranged to delay the power-on reset signal to generate a delayed version of the power-on reset signal, for being utilized as another power-on reset signal, and an electronic device equipped with the power-on reset signal generator performs reset control according to the other power-on reset signal.

9. The power-on reset signal generator of claim 8, wherein the output delay circuit controls a delay amount of the other power-on reset signal with respect to the power-on reset signal to be equal to a predetermined value.

10. The power-on reset signal generator of claim 1, wherein the plurality of sets of transistors comprise N sets of transistors, and N is an integer greater than 1.

11. The power-on reset signal generator of claim 10, wherein the power-on reset signal generator utilizes a voltage detection point of voltage detection that the detection circuit performs on the power-supply voltage as a threshold value, to control whether to change a logical state of the power-on reset signal, and the voltage detection point is equal to N times a bandgap voltage parameter.

12. The power-on reset signal generator of claim 11, wherein through configuring the first resistor and said at least one third resistor, the voltage detection point is equal to N times the bandgap voltage parameter.

13. The power-on reset signal generator of claim 12, wherein configuring the first resistor and said at least one third resistor comprises controlling a resistance value of the first resistor and at least one resistance value of said at least one third resistor to conform to a predetermined condition.

14. The power-on reset signal generator of claim 10, wherein N is equal to two.

15. The power-on reset signal generator of claim 10, wherein N is greater than two.

16. The power-on reset signal generator of claim 1, wherein the comparator comprises a positive input terminal and a negative input terminal; a first terminal and a second terminal of the first resistor are coupled to the power-supply voltage and the ground voltage via multiple partial paths of the first current path, respectively, and a first terminal and a second terminal of the second resistor are coupled to the power-supply voltage and the ground voltage via multiple partial paths of the second current path, respectively; and the positive input terminal of the comparator is coupled to the first terminal of the first resistor, and the negative input terminal of the comparator is coupled to the second terminal of the second resistor.

17. An electronic device equipped with the power-on reset signal generator of claim 1, comprising:
a processing circuit, arranged to control operations of the electronic device;
a power-supply circuit, coupled to the processing circuit, the power-supply circuit arranged to provide power to the processing circuit; and
a reset control circuit, coupled to the processing circuit and the power-supply circuit, the reset control circuit arranged to perform reset control on the processing circuit according to the power-on reset signal, wherein the reset control circuit comprises the power-on reset signal generator.
